(19) United States
(12) Patent Application Publication
(10) Pub. No.: US 2016/0155683 A1
(43) Pub. Date: Jun. 2, 2016

(54) SEMICONDUCTOR PACKAGE HAVING HEAT-DISSIPATION MEMBER

(71) Applicant: Samsung Electronics Co., Ltd., Suwon-si (KR)

(72) Inventors: Sangwon KIM, Seoul (KR); Seunggeol NAM, Yongin-si (KR); Hyeonjin SHIN, Suwon-si (KR); Haeryong KIM, Seongnam-si (KR); Seongjun PARK, Seoul (KR)

(21) Appl. No.: 14/955,112

(22) Filed: Dec. 1, 2015

(30) Foreign Application Priority Data
Dec. 1, 2014 (KR) 10-2014-0169977

(51) Int. Cl. H01L 23/367; H01L 23/00; H01L 23/31

(52) U.S. Cl. CPC H01L 23/367; H01L 23/3107; H01L 24/14; H01L 2224/141

(57) ABSTRACT

A semiconductor package includes a semiconductor chip on a substrate, a thermal conductive film on a lower surface of the semiconductor chip, the thermal conductive film facing the substrate, and a molding member on the substrate and surrounding a sidewall of the semiconductor chip.

### CROSS REFERENCE TO RELATED APPLICATION

This application claims the benefit of Korean Patent Application No. 10-2014-0169977, filed on Dec. 1, 2014, in the Korean Intellectual Property Office, the disclosure of which is incorporated herein in its entirety by reference.

### BACKGROUND

1. Field

Example embodiments relate to a semiconductor package having a thermal conductive film.

2. Description of the Related Art

Due to the recent trend of miniaturization, thinness, and relatively high speed of electronic devices that include semiconductor devices, semiconductor packages have also been miniaturized and highly integrated. When a highly integrated semiconductor package performs a relatively high speed and relatively high performance operation, heat is mainly generated from an internal area of the semiconductor package. Thus, the characteristic of the semiconductor package and an electronic device that includes the semiconductor package to dissipate heat to the external environment is essential for ensuring an operational stability and reliability of the electronic device. Accordingly, highly integrated semiconductor packages include various heat dissipation systems.

Generally, a heat dissipation system of a semiconductor package includes a thermal dissipator having a relatively high heat transfer characteristic and a thermal conduction member that directly contacts the semiconductor package. The heat dissipation system is installed on a region opposite to a region of a semiconductor chip included in the semiconductor package where heat is mainly generated, and thus, the heat dissipation speed from the semiconductor chip is relatively slow. Therefore, degradation of the semiconductor chip may occur.

### SUMMARY

Example embodiments provide a semiconductor package including a semiconductor chip that has a thermal conductive film on a surface thereof facing a substrate.

Additional aspects will be set forth in part in the description which follows and, in part, will be apparent from the description, or may be learned by practice of the presented example embodiments.

According to example embodiments, a semiconductor package includes a semiconductor chip on a substrate, a thermal conductive film on a lower surface of the semiconductor chip, the thermal conductive film facing the substrate, and a molding member on the substrate and surrounding a sidewall of the semiconductor chip.

The thermal conductive film may include a plurality of first holes, and the semiconductor package may further include a chip bump in each of the plurality of first holes, the chip bump contacting the lower surface of the semiconductor chip and an upper surface of the substrate.

The thermal conductive film may include one of BN, ZnO, Al₂O₃, MgO, AlN, and SiC.

The thermal conductive film may have a thickness in a range from about 0.3 nm to about 100 μm.

The semiconductor package may further include an adhesive between the thermal conductive film and the semiconductor chip.

The adhesive may be an epoxy resin.

The thermal conductive film may include an extension unit extending in a horizontal direction from the thermal conductive film, and the extension unit may be embedded in the molding member.

The extension unit may include a plurality of second holes.

The extension unit may extend in parallel to the substrate from the thermal conductive film.

The extension unit may be exposed to an external environment.

The extension unit may have a shape bended from the thermal conductive film towards an upper surface of the substrate.

### BRIEF DESCRIPTION OF THE DRAWINGS

These and/or other aspects will become apparent and more readily appreciated from the following description of the example embodiments, taken in conjunction with the accompanying drawings in which:

FIGS. 1A and 1B are schematic cross-sectional views of a structure of semiconductor packages having a thermal conductive film according to example embodiments;

FIG. 2 is a schematic cross-sectional view of a structure of a semiconductor package having a thermal conductive film according to example embodiments; and

FIG. 3 is a schematic cross-sectional view of a structure of a semiconductor package having a thermal conductive film according to example embodiments.

### DETAILED DESCRIPTION

Reference will now be made in detail to example embodiments, examples of which are illustrated in the accompanying drawings. In the drawings, the thicknesses of layers and regions are exaggerated for clarity. Example embodiments are capable of various modifications and may be embodied in many different forms. It will be understood that when an element or layer is referred to as being “on” another element or layer, the element or layer may be directly on another element or layer or intervening elements or layers. Like reference numerals in the drawings denote like elements throughout the specification, and thus their description will be omitted.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises”, “includes”, “including” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, semiconductor package 100a and 100b having a thermal conductive film according to example embodiments will be described.

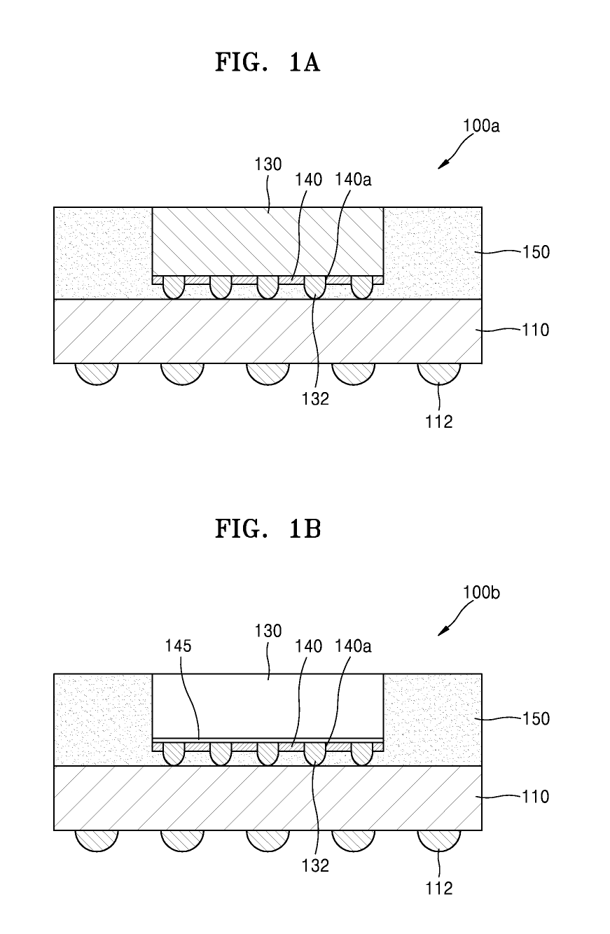

FIGS. 1A and 1B are schematic cross-sectional views of a structure of the semiconductor packages 100a and 100b having a thermal conductive film according to example embodiments.

Referring to FIG. 1A, the semiconductor package 100a according to example embodiments includes a semiconductor chip 130 formed on a substrate 110 and a molding member 150 that surrounds the semiconductor chip 130.

The substrate 110 may be a rigid printed circuit board, a flexible printed circuit board, or a rigid-flexible printed circuit board. Solder balls 112 for electrical connection to a module substrate on which the substrate 110 is mounted may be formed on a lower surface of the substrate 110.

The solder balls 112 may electrically connect electrode pads (not shown) on the substrate 110 to electrode pads (not shown) on the module substrate.

The semiconductor chip 130 may include a logic semiconductor device, e.g., a microprocessor. A thermal conductive film 140 is formed on a lower surface of the semiconductor chip 130. A plurality of first holes 140a may be formed in the thermal conductive film 140. A plurality of chip bumps 132 may be formed on the lower surface of the semiconductor chip 130 to fill the plurality of first holes 140a. The chip bumps 132 may protrude from the lower surface of the semiconductor chip 130. The semiconductor chip 130 may be attached to the substrate 110 by flip chip bonding using the chip bumps 132.

The thermal conductive film 140 may be disposed to contact a lower surface of the semiconductor chip 130. The thermal conductive film 140 may be formed of a material having an insulating property and relatively high thermal conductivity. The thermal conductive film 140 may be formed of, for example, BN, ZnO, Al₂O₃, MgO, AlN, or SiC. The thermal conductive film 140 may have a thickness in a range from about 0.3 nm to about 100 μm. If the thermal conductive film 140 having a thickness of 1 μm or less is formed, because the thermal conductive film 140 has an inherent cohesiveness, the thermal conductive film 140 may be attached to the lower surface of the semiconductor chip 130 without using an additional adhesive.

When the thermal conductive film 140 is formed of boron nitride that has a relatively high thermal conductivity approximately in a range from about 300 to about 400 W/mK, the dissipation of heat may be effectively increased.

However, example embodiments are not limited thereto. For example, in FIG. 1B, the thermal conductive film 140 may be attached to the lower surface of the semiconductor chip 130 by an adhesive 145, for example, an epoxy resin or a double-sided adhesive tape, between the thermal conductive film 140 and the semiconductor chip 130. The adhesive 145 may be formed only on a part of a region between the thermal conductive film 140 and the semiconductor chip 130.

The thermal conductive film 140 directly contacts electrode pads where heat generated from the semiconductor chip 130 is mainly collected, and thus, the heat generated from the semiconductor chip 130 is effectively transmitted to the molding member 150.

The molding member 150 is formed to surround a side surface of the semiconductor chip 130 and the chip bumps 132 fill gaps between the thermal conductive film 140 and the substrate 110. The molding member 150 may include an epoxy molding compound (EMC). The molding member 150 dissipates heat transmitted from the thermal conductive film 140 to the external environment.

In the semiconductor packages 100a and 100b according to example embodiments, because heat generated from the semiconductor chip 130 is more rapidly or easily transmitted to the molding member 150 by directly contacting the thermal conductive film 140 with a heat source (the electrode pads), damage to the semiconductor packages 100a and 100b by a thermal degradation may be reduced.

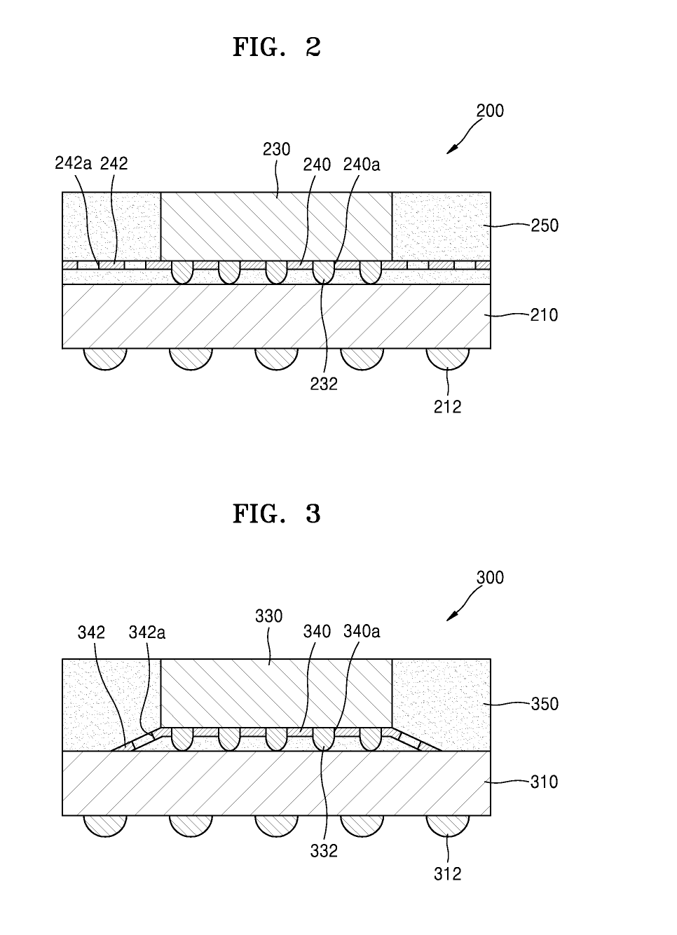

FIG. 2 is a schematic cross-sectional view of a structure of a semiconductor package 200 having a thermal conductive film 240 according to example embodiments.

Referring to FIG. 2, the semiconductor package 200 having the thermal conductive film 240 according to example embodiments includes a semiconductor chip 230 disposed on a substrate 210 and a molding member 250 that surrounds the semiconductor chip 230.

The substrate 210 may be a rigid printed circuit board, a flexible printed circuit board, or a rigid-flexible printed circuit board. Solder balls 212 for electrical connection to a module substrate on which the substrate 210 is mounted may be formed on a lower surface of the substrate 210.

The solder balls 212 may electrically connect electrode pads (not shown) on the substrate 210 to electrode pads (not shown) on the module substrate.

The semiconductor chip 230 may include a logic semiconductor device, e.g., a microprocessor. The thermal conductive film 240 is formed on a lower surface of the semiconductor chip 230. A plurality of first holes 240a may be formed in the thermal conductive film 240. The thermal conductive film 240 may include an extension unit 242 embedded in the molding member 250 in a horizontal direction. The extension unit 242 may be formed to be exposed to the external environment.

A plurality of chip bumps 232 may be formed on a lower surface of the semiconductor chip 230. The chip bumps 232 may protrude from a lower surface of the thermal conductive film 240. The semiconductor chip 230 may be attached to the substrate 210 by flip chip bonding using the chip bumps 232.

A plurality of second holes 242a may be formed in the extension unit 242 of the thermal conductive film 240. The second holes 242a may be used as passages for the molding member 250 to fill a gap between the substrate 210 and the thermal conductive film 240.

The thermal conductive film 240 may be formed to contact the lower surface of the semiconductor chip 230. The thermal conductive film 240 may be formed of a material having an insulating property and relatively high thermal conductivity. The thermal conductive film 240 may be formed of, for example, BN, ZnO, AI₂O₃, MgO, AlN, or SiC. The thermal conductive film 240 may have a thickness in a range from about 0.3 nm to about 100 μm. If the thermal conductive film 240 having a thickness of 1 μm or less is used, because the thermal conductive film 240 has an inherent cohesiveness, the thermal conductive film 240 may be attached to the lower surface of the semiconductor chip 230 without using an additional adhesive.

When the thermal conductive film 240 is formed of boron nitride that has a relatively high thermal conductivity approximately in a range from about 300 to about 400 W/mK, the dissipation of heat may be effectively increased.

However, example embodiments are not limited thereto, that is, the thermal conductive film 240 may be attached to the lower surface of the semiconductor chip 230 by using an adhesive, for example, an epoxy resin or a double-sided adhesive tape, between the thermal conductive film 240 and the semiconductor chip 230.

The adhesive may be formed only on a part of a region between the thermal conductive film 240 and the semiconductor chip 230.

The thermal conductive film 240 directly contacts electrode pads where heat generated from the semiconductor chip 230 is mainly collected, and thus, the heat generated from the semiconductor chip 230 is effectively transmitted to the molding member 250.

The molding member 250 is formed to surround a side surface of the semiconductor chip 230 and the chip bumps 232 fill gaps between the thermal conductive film 240 and the substrate 210. The molding member 250 may include an EMC. The molding member 250 dissipates heat transmitted from the thermal conductive film 240 to the external environment.

In the semiconductor package 200 according to example embodiments, the extension unit 242 is formed as one body with the thermal conductive film 240, but example embodiments are not limited thereto. For example, the extension unit 242 may be formed to contact the thermal conductive film 240, but is not configured to be one body with the thermal conductive film 240.

In the semiconductor package 200 according to example embodiments, heat generated from the semiconductor chip 230 is transmitted to the thermal conductive film 240 that directly contacts a heat source (electrode pads) and to the extension unit 242 of the thermal conductive film 240 that is formed of a material having a higher conductivity than the molding member 250, and thus, the heat is more rapidly or easily transmitted to the molding member 250 and is dissipated to the external environment. Therefore, damage to the semiconductor package 200 due to thermal degradation may be reduced.

FIG. 3 is a schematic cross-sectional view of a structure of a semiconductor package 300 having a thermal conductive film 340 according to example embodiments.

Referring to FIG. 3, the semiconductor package 300 having the thermal conductive film 340 according to example embodiments includes a semiconductor chip 330 disposed on a substrate 310 and a molding member 350 that surrounds the semiconductor chip 330.

The substrate 310 may be a rigid printed circuit board, a flexible printed circuit board, or a rigid-flexible printed circuit board. Solder balls 312 for electrical connection to a module substrate on which the substrate 310 is mounted may be formed on a lower surface of the substrate 310.

The solder balls 312 may electrically connect electrode pads (not shown) on the substrate 310 to electrode pads (not shown) on the module substrate.

The semiconductor chip 330 may include a logic semiconductor device, e.g., a microprocessor. The thermal conductive film 340 is disposed on a lower surface of the semiconductor chip 330. A plurality of first holes 340a may be formed in the thermal conductive film 340. The thermal conductive film 340 may extend to form an extension unit 342 embedded in the molding member 350. Edges of the extension unit 342 may contact or almost contact an upper surface of the substrate 310.

A plurality of chip bumps 332 may be formed on a lower surface of the semiconductor chip 330 to fill the plurality of first holes 340a. The chip bumps 332 may protrude from the lower surface of the semiconductor chip 330. The semiconductor chip 330 may be attached to the substrate 310 by flip chip bonding using the chip bumps 332.

A plurality of second holes 342a may be formed in the extension unit 342 of the thermal conductive film 340. The second holes 342a may be used as a passage for the molding member 350 to fill a gap between the substrate 310 and the thermal conductive film 340.

The thermal conductive film 340 may be formed to contact the lower surface of the semiconductor chip 330. The thermal conductive film 340 may be formed of a material having an insulating property and relatively high thermal conductivity. The thermal conductive film 340 may be formed of, for example, BN, ZnO, AI₂O₃, MgO, AlN, or SiC. The thermal conductive film 340 may have a thickness in a range from about 0.3 nm to about 100 μm. If the thermal conductive film 340 having a thickness of 1 μm or less is used, because the thermal conductive film 340 has an inherent cohesiveness, the thermal conductive film 340 may be attached to the lower surface of the semiconductor chip 330 without using an additional adhesive.

When the thermal conductive film 340 is formed of boron nitride that has a relatively high thermal conductivity in a range from about 300 W/mK to about 400 W/mK, the dissipation of heat may be effectively increased.

However, example embodiments are not limited thereto, that is, the thermal conductive film 340 may be attached to the semiconductor chip 330 by using an adhesive, for example, an epoxy resin or a double-sided adhesive tape between the thermal conductive film 340 and the semiconductor chip 330. The adhesive may be formed only on a part of a region between the thermal conductive film 340 and the semiconductor chip 330.

The thermal conductive film 340 directly contacts electrode pads where heat generated from the semiconductor chip 330 is mainly collected, and thus, the heat generated from the semiconductor chip 330 is effectively transmitted to the molding member 350.

The molding member 350 is formed to surround a side surface of the semiconductor chip 330 and the chip bumps 332 fill gaps between the thermal conductivity film 240 and the substrate 210. The molding member 350 may include an EMC. The molding member 350 dissipates heat transmitted from the thermal conductive film 340 to the external environment.

In the semiconductor package 300 according to example embodiments, heat generated from the semiconductor chip 330 is transmitted to the thermal conductive film 340 that directly contacts a heat source (electrode pads) and to the extension unit 342 of the thermal conductive film 340 that is formed of a material having a higher conductivity than the molding member 350, and thus, the heat is more rapidly or easily transmitted to the molding member 350. Therefore, damage to the semiconductor package 300 due to thermal degradation may be reduced.

While example embodiments have been described with reference to the figures, it will be understood by those of ordinary skill in the art that various changes in form and details may be made therein without departing from the spirit and scope as defined by the following claims.

What is claimed is:

1. A semiconductor package comprising:
a semiconductor chip on a substrate;
a thermal conductive film on a lower surface of the semiconductor chip, the thermal conductive film facing the substrate; and
a molding member on the substrate and surrounding a sidewall of the semiconductor chip.

2. The semiconductor package of claim 1, wherein the thermal conductive film includes a plurality of first holes, further comprising:
a chip bump in each of the plurality of first holes, the chip bump contacting the lower surface of the semiconductor chip and an upper surface of the substrate.

3. The semiconductor package of claim 1, wherein the thermal conductive film includes one of BN, ZnO, Al₂O₃, MgO, AlN, and SiC.

4. The semiconductor package of claim 3, wherein the thermal conductive film has a thickness in a range from about 0.3 nm to about 100 μm.

5. The semiconductor package of claim 1, further comprising:
an adhesive between the thermal conductive film and the semiconductor chip.

6. The semiconductor package of claim 5, wherein the adhesive is an epoxy resin.

7. The semiconductor package of claim 1, wherein the thermal conductive film includes an extension unit extending in a horizontal direction from the thermal conductive film, the extension unit being embedded in the molding member.

8. The semiconductor package of claim 7, wherein the extension unit includes a plurality of second holes.

9. The semiconductor package of claim 7, wherein the extension unit extends in parallel to the substrate from the thermal conductive film.

10. The semiconductor package of claim 9, wherein the extension unit is exposed to an external environment.

11. The semiconductor package of claim 7, wherein the extension unit has a shape bended from the thermal conductive film towards an upper surface of the substrate.
